(19) United States
(12) Patent Application Publication
(10) Pub. No.: US 2002/0090576 A1
(43) Pub. Date: Jul. 11, 2002

(54) Dual damascene semiconductor device and method

(76) Inventor: Jui-Neng Tu, Hsinchu City (TW)

Correspondence Address: HAYNES BEFFEL & WOLFELD LLP, P O BOX 366, HALF MOON BAY, CA, 94019, US

(21) Appl. No.: 09/850,488

(22) Filed: May 7, 2001

(30) Foreign Application Priority Data
Jan. 10, 2001 (TW) 90100508

(51) Int. Cl. G03F 7/00

(52) U.S. Cl. 430/311; 430/312; 430/314; 430/316; 430/317

(57) ABSTRACT

A dual damascene semiconductor device (38) includes a first insulation layer (12) with a first electrical contact (14). A second insulation layer (20), having an outer surface (40), is formed over the first insulation layer and a trench (26) is preferably formed in the outer surface of the second insulation layer. The second insulation layer is a continuous, nonlayered layer of material. A second electrical contact (36) is embedded within the second insulation layer, typically within the trench. An electrical connection (34) passes through a via (hole) (32) formed in the second insulation layer to electrically connect the first and second electrical contacts. An etching-stop layer (18) may be used between the first and second insulation layers. The metal connection and electrical contacts may be made of copper. This invention applied the top surface image method to the via photo step. The application of the top surface image method improves the tolerance of the via (hole) photo process and also helps to solve the high resistance problem when misalignment occurs at the via (hole) photo step.

### BACKGROUND OF THE INVENTION

Lithography is commonly used in creating circuitry for semiconductor devices. One of the primary challenges in the production of semiconductor devices involves the ability to create circuits of increasing density with smaller and smaller critical dimensions. For the sub-micron semiconductor devices, the lithography process for pattern transfer onto the production wafers becomes a more difficult process for the resolution requirement is much critical than ever. In response to this, top surface image (TSI) technique was proposed to solve the problems might be encountered in the sub-quarter micron patterning process. Using TSI, the resist surface of the exposed (or unexposed) area is silylated while the unexposed (or exposed) area is not silylated. Top surface image process uses reactive ion etching (RIE) to do dry development after exposure and silylation of a photoresist pattern. A dry development in the top surface image process requires high selectivity between the silylated and non-silylated areas of the photoresist. See, for example, U.S. Pat. Nos. 5,322,765; 5,312,717; and 4,808,511.

The damascene semiconductor processing method differs from conventional semiconductor processing methods in that the metal lines are not etched, but are deposited in grooves formed within the dielectric layer. Excess metal is then removed by chemical mechanical polish (CMP) techniques. The single damascene process involves oxide trench patterning, oxide trench or hole imaging, metal filling and metal CMP. The dual damascene process involves simultaneously filling both the oxide trench and the hole with metal. The damascene process and the dual damascene process are very well suited for laying metal lines and interconnects on chips. Another advantage of the damascene process is that the many of the processing problems associated with metal etch steps, including corrosion, resist burn, time critical with resist, etc., are eliminated. This is because all patterning is done with oxide etching or other dielectric etching. This makes the damascene process especially well suited for copper interconnect because of the difficulties encountered in the copper dry etch process.

Currently, two basic approaches for creation of the dual damascene structure are the via-first and the trench-first. With the via-first approach, there is typically an intermediate etching-stop layer between the top and bottom intermetallic dielectric (IMD) layer for better via critical dimension (CD) control. This intermediate layer is typically formed with a material of high etching selectivity to the IMD material and usually has a higher dielectric constant which, however, has a deleterious effect on the speed of the device. However, poor via profile it may be observed if the intermediate layer is not use. This may also be a problem for CD control as the device shrinks in size.

FIGS. 1-4 illustrate a conventional trench-first dual damascene process. FIG. 1 illustrates a device subassembly 10 including a first insulation layer 12 with a first electrical contact 14, typically made of copper, formed therein. Layer 12 has a first surface 16 over which an etching-stop layer 18, typically an insulating material, has been deposited. A second insulating layer 20 is deposited on top of layer 18. Layer 20 has a second surface 22 which overlies first surface 16 and contacts layer 18. A third insulating layer 24 is deposited on top of layer 20. A third layer 24 has a trench 26 formed therein, typically by conventional photo patterning methods. FIG. 2 illustrates a photoresist layer 28 formed on the structure of FIG. 1 using conventional photo patterning methods, that is photoresist layer, exposure and development, to create a first hole 30. FIG. 3 illustrates the formation of a second hole (via) 32 through second insulation layer 20 and etching-stop layer 18 and the removal of photoresist layer 28. Finally, at FIG. 4, second hole 32 and trench 26 are shown filled with copper to create a metal connection 34 within second hole 32 and a second electrical contact 36 within trench 26.

The problem for the trench-first dual damascene process is the development resolution of the hole pattern. The thicker photoresist in the trench area makes the exposure and development very difficult to define the desired hole size. Besides, the overlay shift for the trench-first dual damascene process is another problem for the hole patterning and etching. The problem of misalignment between the different layers involved increases as feature sizes are decreased. Misalignment problem with trench first damascene processes may cause the via size to shrink, resulting in high resistance and reliability problems.

### SUMMARY OF THE INVENTION

The present invention is directed to a dual damascene semiconductor device and a method for forming the device. The invention provides benefits as compared with the conventional trench-first dual damascene process. First, this invention can provide a method forming the dual damascene structure within a single continuous dielectric layer without an intermediate etch-stop layer, while still keeping good hole CD (critical dimension) control. Without the intermediate etch-stop layer, the device performance can still be maintained. Second, the hole patterning process may not be as difficult when compared with conventional photo patterning. With the present invention, the resolution and DOF (depth of focus) requirement for small-sized holes can be more easily achieved than with conventional patterning methods. Third, this invention can provide a solution to the misalignment problem between the trench and the hole patterning layer by adjusting the hole etching recipe steps. Overall, this invention can give a wider tolerance to the photo process which can reduce the process tuning and photo rework costs while maintaining good device performance.

A first aspect of the invention is directed to the dual damascene semiconductor device comprising a first insulation layer with a first electrical contact. A second insulation layer overlies the first insulation layer. The second insulation layer is a continuous, nonlayered layer of material. A second electrical contact is embedded within the second insulation layer, typically within a trench. An electrical connection passes through a hole (via) formed in the second insulation layer to electrically connect the first and second electrical contacts. An etching-stop layer is preferably used between the first and second insulation layers. The metal connection and electrical contacts may be made of copper.

Another aspect of the invention is directed to a method for forming a dual damascene semiconductor device. A device subassembly, comprising a first insulation layer having a first electrical contact, is made. A second insulation layer, having an outer surface, is formed over the first insulation layer and a trench is formed in the outer surface of the second insulation layer. The trench overlies the first electrical contact. A photoresist layer is formed over at least a portion of the outer surface. A first hole, which is at least partially aligned with the trench, is formed completely through the photoresist layer. A second hole (via), which is at least partially aligned with the first hole, is formed through the second insulation layer and extends to the first electrical contact. The remaining photoresist layer is removed. The trench and the second hole are at least partially filled with an electrically conductive material, such as copper, thus electrically connecting the first and second electrical contacts. The first hole-forming step may be carried out with the first hole being only partially aligned with the trench. In such case the first hole forming step will include: forming a preliminary hole in the photoresist layer leaving photoresist at the bottom of the trench, removing the portion of the second insulation layer that is intersected by the first hole, and removing the photoresist at the bottom of the preliminary hole, thus creating the first hole.

Other features and advantages of the invention will appear from the following description in which the preferred embodiments have been set forth in detail in conjunction with the accompanying drawings.

### BRIEF DESCRIPTION OF THE DRAWINGS

FIGS. 1-4 schematically illustrate a conventional trench-first dual damascene process;

FIGS. 5-12 illustrate a trench-first, dual damascene process according to the invention including the dual damascene semiconductor device made thereby; and

FIGS. 13-18 illustrate an alternative to the process shown in FIGS. 5-12 when the first hole is misaligned with the trench.

### DETAILED DESCRIPTION

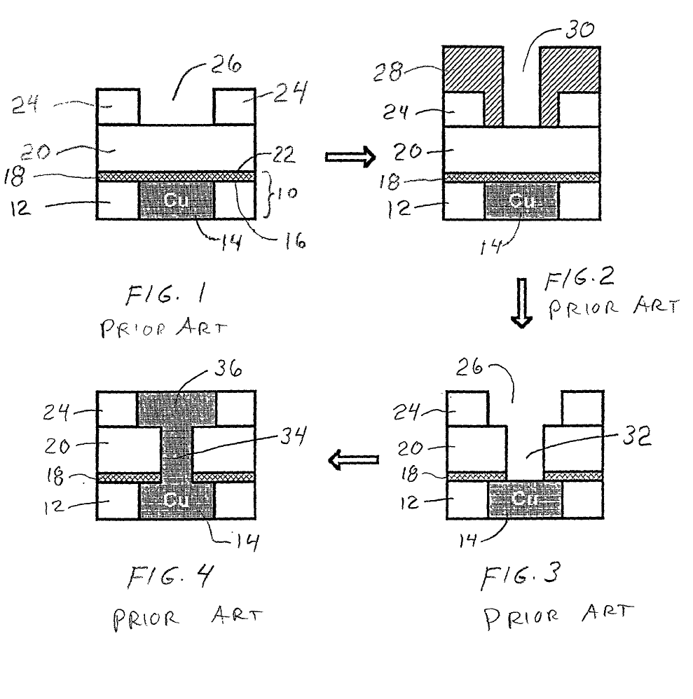

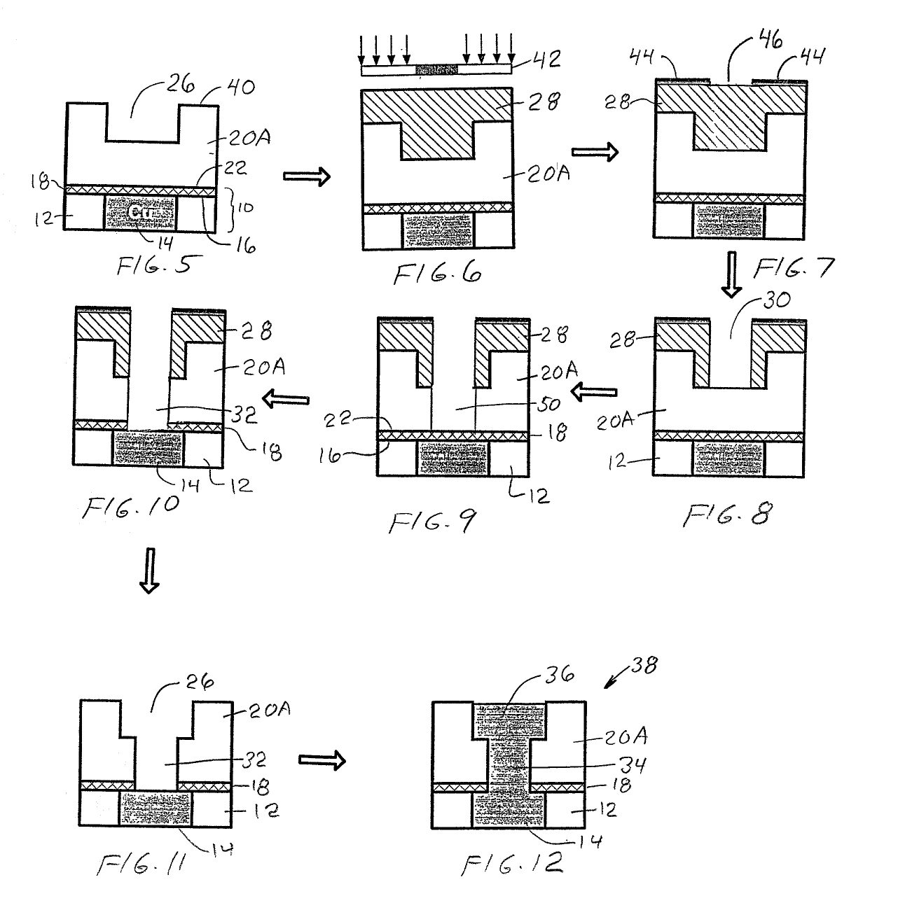

FIGS. 5-12 illustrate a trench-first, dual damascene process according to the invention including the dual damascene semiconductor device 38 (see FIG. 12) made thereby. The process is quite similar to that discussed above with regard to FIGS. 1-4 with like reference numerals referring to like elements. The primary differences are as follows. As shown in FIG. 5, there is no third insulation layer 24 as in the conventional method illustrated in FIGS. 1-4; rather, second insulation layer 20A has trench 26 formed in its third surface 40. Second insulation layer 20A can thus be described as nonlayered as opposed to the layering of insulation layers 20, 24 of FIG. 1. The elimination of third insulation layer 24 provides better performance in device speed because the intermediate etching-stop layer is usually material with high dielectric constant. If the intermediate etching-stop layer exists, the effective interlayer dielectric constant will be increased and which is detrimental to the device performance.

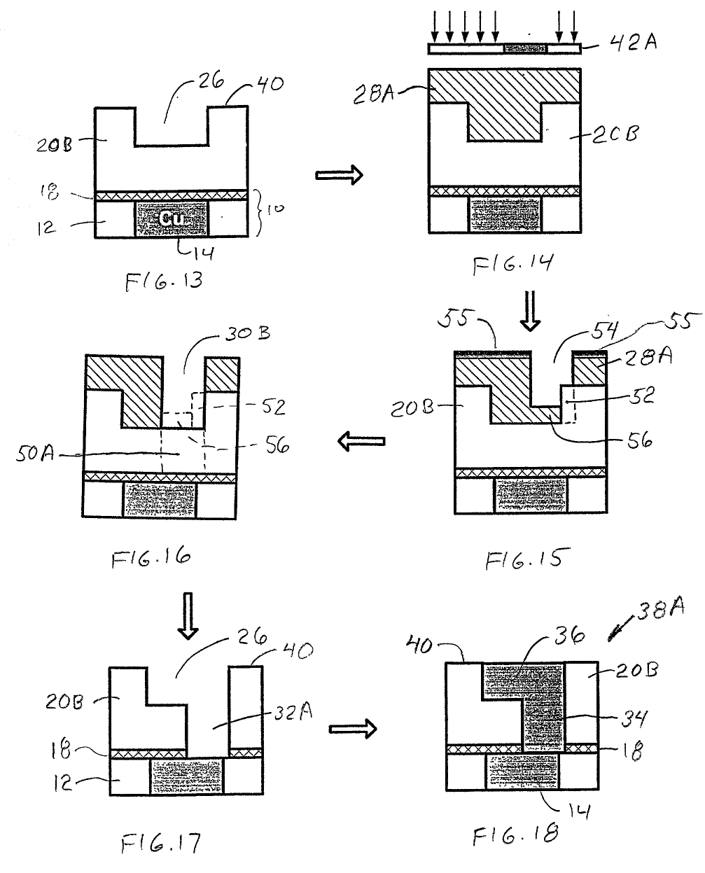

The process of making device 38 proceeds generally as follows. Device subassembly 10 is made and has second insulation layer 20A formed over first surface 16 of first insulation layer 12. It is preferred that device subassembly 10 include etching-stop layer 18, the etching-stop layer being optional. After forming layer 20A, trench 26 is formed in third surface 40 of layer 20A by conventional techniques; these techniques typically include applying a first photoresist layer (not shown) on second insulation layer 20A, forming a trench pattern on the first photoresist layer; partially etching second insulation layer 20A to transfer the trench pattern to the second insulation layer; and then removing the first photoresist layer. A second photoresist layer 28 is then formed on top of third surface 40 and fills trench 26. First hole 30 is formed in photoresist layer 28 using top surface imaging lithography techniques. As shown in FIGS. 6 and 7, a mask 42 is used to create exposed, silicon-containing silylated areas 44 and unexposed, non silylated area 46 on photoresist surface 48. Non silylated area 46 is preferably directly aligned with trench 26. The procedure followed when non sillyated area 46 is only partially aligned with trench 26 will be discussed with reference to FIGS. 13-18. The unexposed, non silyated area 46 is then etched by masking of the silated area 44 using dry development techniques to create first hole 30 down to the bottom of trench 26 as shown in FIG. 8. An outer end 50 of second hole (via) 32, aligned with first hole 30, is etched through second insulation layer 20A and down to etching-stop layer 18. Photoresist layer 28 is then masked and the portion of etching-stop layer 18 between second hole 32 and first electrical contact 14 is then removed by etching as shown in FIG. 10 to create second hole (via) 32. The remaining photoresist layer 28 is then removed as illustrated in FIG. 11. Second hole (via) 32 and trench 26 are filled with a conductive material, preferably a metal, typically copper, to create metal connection 34 and second electrical contact 36. Excess metal on third surface 40 or any portion of contact 36 lying above the plane of surface 40 is removed by CMP, thus forming dual damascene semiconductor device 38.

The dual damascene process is especially suited for copper deposition. However, metals other than copper could be used. First and second insulation layers 12, 20A may be SiO2 or other doped SiO2 such as BPSG (boron and phosphorus doped) or FSG (fluorine doped) which has good selectivity to photoresist. Etching-stop layer 18 may, for example, be SiN or SiON each of which has good selectivity to the first and second insulation layers. The via photo process described above is the positive-tone top-surface imaging process. However, both positive and negative tone top-surface imaging can be applied to the via photo step. Also, while metal connection 34 is shown to be a solid metal connections completely filling second hole 32, metal connection 34 could be formed along the walls defining second hole 32. First and second electrical contacts 14, 36 are preferably metal is lines; they could be other types of electrical contacts, such as silicon contacts, silicide or polycide contacts.

The process for producing the dual damascene semiconductor device 38A of FIG. 18 is similar to that of FIGS. 5-12 with the following changes. If mis-alignment occurs, mask 42A is slightly misaligned so that the first hole 30A intersects a portion 52 of second insulation layer 20B. When this occurs, first hole 30A is created in steps. First, a preliminary hole 54 is formed in photoresist layer 28A (by TSI and dry development), as shown in FIG. 15, in a manner to leave an unexposed portion 56 of photoresist at the bottom of preliminary hole 54. The unexposed area 55 of photoresist layer 28A and the portion 56 of the remaining photoresist layer at the bottom of the preliminary hole are masked. Portion 52 of second insulation layer 20B is then removed by etching to the bottom of the trench. After portion 52 is etched to the bottom of the trench, the photoresist portion 56 at the bottom of the hole 54 is removed simultaneously with the etching of that portion of second insulation layer 20B. An additional photoresist dry etching step is needed to ensure that there is no photoresist remaining at the bottom of the first hole 54. The following oxide etching etches the hold below trench 54 to create the outer end 50A of second hole (via) 32A. The etching-stop layer 18 under outer end 50A of second hole 32A is removed using oxide etching techniques.

Metal connection 34 and first electrical contact 36 are then formed by filling trench 26 and second hole (via) 32A with copper, or some other suitable electrically conductive material, thereby electrically connecting second electrical contact 36 with first electrical contact 14. Excess metal on third surface 40 or any portion of contact 36 lying above the plane of surface 40 is removed by CMP, thus forming dual damascene semiconductor device 38A.

Modification and variation may be made to the disclosed embodiments without departing from the subject of the invention as defined in the following claims.

Any and all patents, patent applications and printed publications referred to above are hereby incorporated by reference.

1. A dual damascene semiconductor device comprising:
a first insulation layer having a first surface and a first electrical contact at the first surface;
a second insulation layer overlying the first insulation layer and having second and third surfaces;
the second insulation layer being a continuous, non-layered layer of material;
a second electrical contact embedded within the second insulation layer and generally aligned with the third surface; and
an electrical connection, passing through a hole formed in the second insulation layer, electrically connecting the first and second electrical contacts.

2. The device according to claim 1 further comprising an etching-stop layer between and in contact with the first and second surfaces.

3. The device according to claim 1 wherein the first and second electrical contacts comprise first and second metal lines, respectively.

4. The device according to claim 3 wherein the metal lines and the electrical connection are made of copper.

5. The device according to claim 1 wherein the electrical connection contacts the first insulation layer.

6. The device according to claim 1 wherein the second electrical contact has sides that are generally perpendicular to the third surface.

7. The device according to claim 1 wherein the electrical connection has sides that are generally perpendicular to the third surface.

8. The device according to claim 1 wherein the electrical connection is a solid metal connection.

9. A method for forming a dual damascene semiconductor device comprising:
making a device subassembly comprising a first insulation layer having a first surface and a first electrical contact at the first surface;
forming a second insulation layer over the first surface of the first insulation layer, the second insulation layer having second and third surfaces, the second surface facing the first surface;
creating a trench in the third surface of the second insulation layer, the trench overlying the first electrical contact;
forming a photoresist layer over at least a portion of the third surface and in the trench;
forming a first hole, at least partially aligned with the trench, completely through the photoresist layer;
forming a second hole, at least partially aligned with the first hole, through the second insulation layer and to the first electrical contact;
removing the remaining photoresist layer; and
at least partially filling the trench and the second hole with an electrically conductive material so to create a second electrical contact in the trench and an electrical connection in the second hole, the first and second electrical contacts electrically connected through the electrical connection.

10. The method according to claim 9 wherein the making step is carried out so the second insulation layer is a continuous, homogeneous layer.

11. The method according to claim 9 wherein the making step is carried out so the device subassembly comprises an etching-stop layer between and in contact with the first and second surfaces.

12. The method according to claim 11 wherein the second hole forming step further comprises removing at least a portion of the etching-stop layer between the second hole and the first electrical contact so to extend the second hole to the first electrical contact.

13. The method according to claim 9 wherein the trench creating step is carried out so that the trench directly overlies and is centered on the first electrical contact.

14. The method according to claim 9 wherein the first hole-forming step is carried out so that the first hole is only partially aligned with the trench.

15. The method according to claim 14 wherein the first hole forming step comprises:
forming a preliminary hole in the photoresist layer leaving photoresist at a bottom of the trench;
removing that portion of the second insulation layer that is intersected by the first hole; and
removing the photoresist at the bottom of the preliminary hole.

16. The method according to claim 9 wherein the first hole-forming step is carried out using top surface imaging lithography comprising:
silylating a portion of the photoresist surface using a lithography mask leaving a non-silylated area at least partially aligned with the trench; and
etching the non-silyated area so to create the first hole.

17. The method according to claim 9 wherein the making and the at least partially filling steps are carried out so that the first and second electrical contacts comprise first and second metal lines.

18. A method for dual damascene structure formation comprising:
producing a first insulation layer having a first surface and an electrical contact at the first surface;
forming an insulating, etching-stop, layer overlaying the first insulation layer, the etching-stop layer acting as an etching-stop layer for a via etch;
forming a second insulation layer overlying on the etching-stop layer, the second insulation layer having an outer surface;
applying a first photoresist layer on the second insulation layer,
forming a trench pattern on the first photoresist layer;
partially etching the second insulation layer to transfer the trench pattern to the second insulation layer;
removing the first photoresist layer;
applying a second photoresist layer on the second insulation layer including the trench pattern;
patterning a via hole on the second photoresist layer;
silyating an exposed area of the second photoresist layer to create a silyated layer;
forming a silicon-containing surface layer on the exposed area of the second photoresist layer;
dry developing the unexposed area for creation of a via hole;
forming a first hole in the second photoresist layer to the bottom of the trench formed in the second insulation layer by etching the unexposed area of the second photoresist layer by the masking of the silyated layer;
etching the second insulation layer thus forming a portion of a second, via hole from the trench bottom to the etching-stop layer;
etching the etching-stop layer to the electrical contact in the first insulation layer to create a via hole;
removing the remaining second photoresist layer;
filling conductive material into the via hole and the trench;
removing any conductive material that may be on the outer surface of the third insulation layer or above the trench, thereby forming a dual damascene interconnect.

19. The method according to claim 18 wherein the filling step is carried out using a conductive material comprising a metal.

20. The method according to claim 18 wherein the filling step is carried out using a conductive material comprising copper.

21. A method for dual damascene structure formation comprising:
producing a first insulation layer having a first surface and an electrical contact at the first surface;
forming an insulating, etching-stop, layer overlaying the first insulation layer, the etching-stop layer acting as an etching-stop layer for a via etch;
forming a second insulation layer overlying on the etching-stop layer, the second insulation layer having an outer surface;
applying a first photoresist layer on the second insulation layer,
forming a trench pattern on the first photoresist layer;
partially etching the second insulation layer to transfer the trench pattern to the second insulation layer;
removing the first photoresist layer;
applying a second photoresist layer on the second insulation layer including the trench pattern;
patterning a via hole on the second photoresist layer;
silyating an exposed area of the second photoresist layer to create a silyated layer;
forming a silicon-containing surface layer on the exposed area of the second photoresist layer;
forming a preliminary hole in the second photoresist layer in a manner to keep a portion of the second photoresist layer at the bottom of the preliminary hole, the preliminary hole exposing a portion of the second insulating layer due to misalignment of the via hole with the trench;
etching the exposed portion of the second insulation layer down to the depth of the trench;
removing the portion of the second photoresist layer remaining at the bottom of the preliminary hole;
etching the second insulation layer thereby forming a portion of the via hole to the surface of the second insulation layer;
etching the etching-stop layer to a surface of the electrical contact in the first insulation layer to create a via hole;
removing the remaining second photoresist layer;
filling conductive material into the via hole and the trench;
removing any conductive material that may be on the outer surface of the third insulation layer or above the trench, thereby forming a dual damascene interconnect.
